(19) United States
(12) Patent Application Publication
(10) Pub. No.: US 2026/0088648 A1
(43) Pub. Date: Mar. 26, 2026

(54) CHARGING SYSTEM AND CHARGING METHOD FOR SECONDARY BATTERY

(71) Applicant: TOYOTA JIDOSHA KABUSHIKI KAISHA, Toyota-shi (JP)

(72) Inventor: Yoshiki TSUCHIDA, Nagoya-shi (JP)

(73) Assignee: TOYOTA JIDOSHA KABUSHIKI KAISHA, Toyota-shi (JP)

(21) Appl. No.: 19/262,671

(22) Filed: Jul. 8, 2025

(30) Foreign Application Priority Data
Sep. 24, 2024 (JP) 2024-165182

(51) Int. Cl. H02J 7/00; G01R 19/165; G01R 31/385; H01M 10/44

(52) U.S. Cl. CPC H02J 7/94; G01R 19/16542; G01R 31/385; H01M 10/44; H02J 7/80

(57) ABSTRACT

A charging system for a secondary battery includes: a current sensor that measures a current flowing in the secondary battery; and a control apparatus that, during charging of the secondary battery, refers to a measurement value of the current sensor and performs charging control of the secondary battery. The current sensor includes a magnetic current sensor. The charging control includes setting of a chargeable current value that is allowed during the charging of the secondary battery. When a ripple is detected from the measurement value of the magnetic current sensor and a current value of the detected ripple is not less than a predetermined current value, the chargeable current value is set using the current value of the detected ripple.

### CROSS-REFERENCE TO RELATED APPLICATION

This application claims priority to Japanese Patent Application No. 2024-165182 filed on Sep. 24, 2024. The disclosure of the above-identified application, including the specification, drawings, and claims, is incorporated by reference herein in its entirety.

### BACKGROUND

### 1. Technical Field

The present disclosure relates to a charging technology for a secondary battery.

### 2. Description of Related Art

Japanese Patent No. 7149543 (JP 7149543 B) discloses a system that charges, using a charger, a secondary battery with alternating current electric power supplied from a commercial power system. A ripple component is occasionally superimposed on output electric power of the charger. A ripple voltage (minute voltage fluctuation) causes voltages of a plurality of cells that constitutes a secondary battery to pulsate. When the pulsation of a cell voltage becomes large, there arises a possibility of exceeding the maximum allowable voltage of the cells. Therefore, a conventional system estimates the ripple voltage of each cell based on the total voltage of the cells and internal impedances of the cells. Moreover, when the estimated ripple voltage of each cell goes up beyond an allowable voltage range, the conventional system disconnects inflow of a charging current from the charger to the secondary battery.

### SUMMARY

The reason why the conventional system disconnects the inflow of the charging current is because the ripple component contained in the charging current brings a harmful influence on the cells. For example, when the secondary battery is a lithium-ion battery, there is a possibility that a ripple current flowing into the lithium-ion battery causes lithium to precipitate.

While the conventional system estimates the ripple voltage of each cell in charging to suspend the charging, the charging may be suspended by directly detecting the ripple component contained in the charging current. The detection of the ripple current in this case is performed using a current sensor. When the ripple current is detected, charging control by which the ripple current is not allowed to flow in the secondary battery is performed.

However, since the ripple current is a high frequency current, detection of the ripple current using a shunt resistor current sensor results in a problem below. There is a possibility that, when the ripple current arises, a ripple current that is larger than the actual value is detected due to characteristics of a shunt resistor that an increase in impedance caused by a skin effect amplifies the frequency of the shunt voltage. This causes a possibility of excessively restricting the charging current in charging control.

An object of the present disclosure is to provide a technology that, when charging control is performed by detecting with a current sensor a ripple current in charging of a secondary battery, enables a charging current to be restrained from being excessively restricted when the ripple current is detected.

A first aspect of the present disclosure is a charging system for a secondary battery, and has features below. The charging system includes:
a current sensor that measures a current flowing in the secondary battery; and
a control apparatus that, during charging of the secondary battery, refers to a measurement value of the current sensor and performs charging control of the secondary battery.

The current sensor includes a magnetic current sensor.

The charging control includes setting of a chargeable current value that is allowed during the charging of the secondary battery.

When a ripple is detected from the measurement value of the magnetic current sensor and a current value of the detected ripple is not less than a predetermined current value, the chargeable current value is set using the current value of the detected ripple.

A second aspect of the present disclosure is a charging method for a secondary battery, and has features below.

The charging method includes:
measuring a current flowing in the secondary battery with a current sensor; and
during charging of the secondary battery, a control apparatus referring to a measurement value of the current sensor and performing charging control of the secondary battery.

The current sensor includes a magnetic current sensor.

The charging control includes setting of a chargeable current value that is allowed during the charging of the secondary battery.

When a ripple is detected from the measurement value of the magnetic current sensor and a current value of the detected ripple is not less than a predetermined current value, the chargeable current value is set using the current value of the detected ripple.

Being different from the shunt resistor current sensor, the magnetic current sensor has characteristics that the frequency of a magnetic field input to a sensor element attenuates due to the skin effect. Therefore, in view of accurate detection of the ripple current, it can be said that the magnetic one is superior to the shunt resistor one. The present disclosure focuses on this viewpoint. Namely, according to the present disclosure, a ripple is accurately detected from the measurement value of the magnetic current sensor. Further, when the current value of the detected ripple is not less than the predetermined current value, the chargeable current value which is allowed during charging of the secondary battery is set using the current value of the detected ripple. Accordingly, the charging current can be restrained from being excessively restricted when the ripple current is detected.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram for explaining a configuration specifically relevant to a charging system according to an embodiment of the present disclosure;

FIG. 2 is a conceptual diagram for explaining a skin effect;

FIG. 3 is a diagram showing an example of frequency characteristics of a shunt voltage;

FIG. 4 is a diagram showing an example of frequency characteristics of a magnetic field input to a magnetic current sensor;

FIG. 5 is a flowchart showing a flow of processing of charging control of a secondary battery specifically relevant to an embodiment; and

FIG. 6 is a diagram showing an example of relationship among a battery current and a minimum value and a 10-millisecond average value of sampling currents.

### DETAILED DESCRIPTION OF EMBODIMENTS

Hereafter, embodiments of the present disclosure will be described with reference to the drawings. Note that a structure or the like described in the embodiments shown below is not necessarily essential to the present disclosure except in the case of being explicitly designated or in the case of being clearly specified in principle.

### 1. Charging System for Secondary Battery

A charging system for a secondary battery according to an embodiment is a system that charges a secondary battery mounted on a vehicle. The vehicle on which the secondary battery is mounted is, for example, a vehicle that can undergo plug-in charging with electric power supplied from a power supply outside the vehicle (external power supply). Examples of the vehicle include plug-in hybrid electric vehicles (PHV and PHEV).

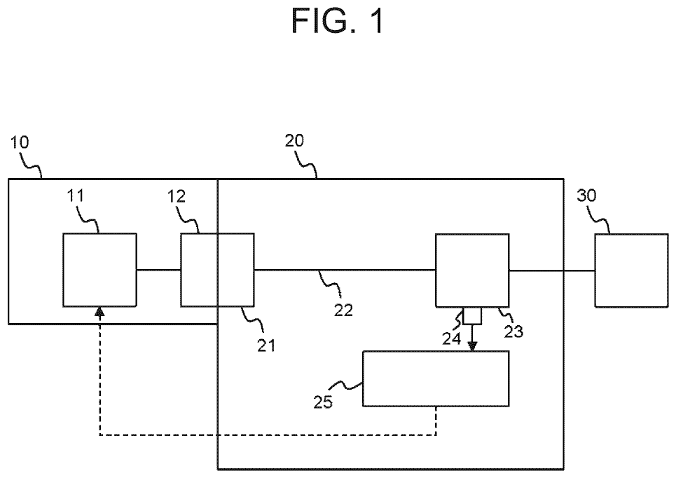

FIG. 1 is a diagram for explaining a configuration specifically relevant to the charging system according to an embodiment. In FIG. 1, an external power supply 10, a power storage system 20, and a motor 30 are drawn. For example, the external power supply 10 is a household single-phase 100-volt alternating current power supply or a single-phase 200-volt alternating current power supply. The external power supply 10 includes a charger 11 and a connector 12.

The charger 11 is a device that performs rapid charging of a secondary battery. For example, the charger 11 includes a boost-step-down converter and various relays (all of which are not shown). The charger 11 performs the rapid charging in response to a charge enabling signal from the power storage system 20. During the rapid charging of the power storage system 20, the charger 11 outputs a direct current corresponding to a chargeable current value Itag[t] from the power storage system 20.

The power storage system 20 is a system mounted on the vehicle. In the example shown in FIG. 1, the power storage system 20 includes a charging inlet lid 21, an electric power line 22, a secondary battery 23, a current sensor 24, and a control apparatus 25.

The charging inlet lid 21 is a site where the connector 12 is inserted. The electric power line 22 connects the charging inlet lid 21 and the secondary battery 23. The electric power line 22 supplies, to the secondary battery 23, the direct current received from the charger 11 through the connector 12. The secondary battery 23 is a power storage apparatus for driving the motor 30. The secondary battery 23 is constituted of a secondary battery, such as a nickel-metal hydride battery or a lithium-ion battery. For example, the secondary battery 23 is constituted of a stack having cells with about 1 V to 5 V stacked.

The current sensor 24 detects a current (battery current) Ib that flows in the secondary battery 23. The current sensor 24 includes two kinds of current sensors, shunt resistor one and magnetic one. For example, the former includes a shunt resistor and a sensor IC. Moreover, the former measures the battery current Ib by amplifying, with an amplifier, a voltage (shunt voltage) arising between both ends of the shunt resistor that is inserted on a current path, and then, by performing processing with the sensor IC. The latter measures the battery current Ib by measuring a magnetic field generated by the flow of the current. The latter is core-including one or coreless one. The core-including sensor measures the magnetic field around the current path via a magnetic core with a sensor IC inserted into a gap of the magnetic core. The coreless sensor directly measures a magnetic field generated by a current drawn into the sensor IC.

The control apparatus 25 is a computer that performs various kinds of control in the vehicle. The control apparatus 25 includes computer hardware including a processor, a memory, and the like, and operates in accordance with software including installed operating system (OS), application programs, and the like. The various kinds of control performed by the control apparatus 25 include charging control of the secondary battery 23. In the charging control of the secondary battery 23, the current value that is allowed during charging of the secondary battery 23 (that is, the chargeable current value Itag) is set and is output to the charger 11.

The motor 30 drives the vehicle on which the power storage system 20 is mounted. To the motor 30, electric power is supplied from the secondary battery 23. The motor 30 converts the electric power supplied from the secondary battery 23 into rotational energy to rotate wheels. The motor 30 may be constituted of a motor-generator. In this case, the motor 30 also operates as a generator. When operating as the generator, the motor 30 converts regenerative energy in deceleration of the vehicle into electric power, which is stored in the secondary battery 23. The motors 30 are sometimes provided in the vehicle.

### 2. Characteristics of Current Sensors

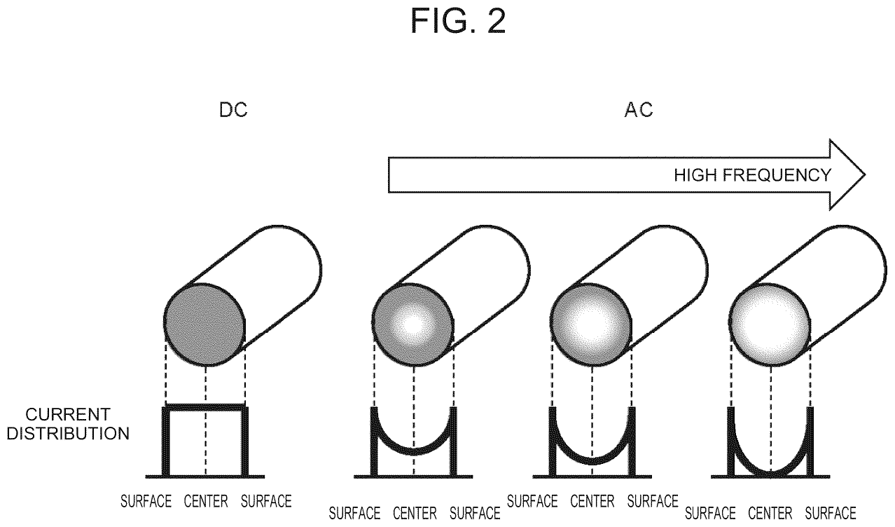

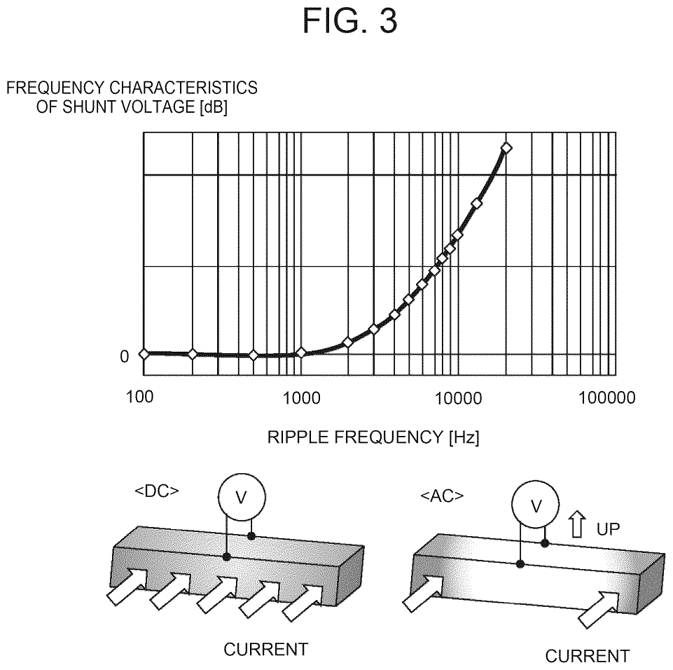

By including the shunt resistor current sensor, the current sensor 24 can measure the battery current Ib by taking advantage of a characteristic of a shunt resistor, that is, a small error. It should be noted that, in charging of the secondary battery 23 from the external power supply 10, the characteristic of the shunt resistor results in a possibility of disturbing accurate measurement of the battery current Ib. This problem is explained with reference to FIGS. 2 and 3.

FIG. 2 is a conceptual diagram for explaining the skin effect. When a direct current is flowing in a lead, a current distribution inside the lead is uniform. In contrast, when an alternating current is flowing in the lead, the current concentrates on the surface of the lead and the current is more difficult to flow as being closer to the center from the surface. This phenomenon is the skin effect. The skin effect is more significant as the frequency of the alternating current is higher. In other words, the alternating current with a high frequency flows on the surface of the lead, and almost no alternating current with the high frequency flows at the center of the lead.

When a ripple component is superimposed on output electric power of the charger 11 in charging from the external power supply 10, the skin effect caused by this ripple component elevates the frequency of the charging current flowing into the secondary battery 23. Therefore, in current detection using the shunt resistor current sensor, an increase in impedance due to the skin effect results in amplifying the frequency of the shunt voltage. FIG. 3 is a diagram showing an example of frequency characteristics of the shunt voltage. As understood from FIG. 3, the frequency of the shunt voltage rises in a high frequency band of frequencies of the charging current (ripple current).

The problem in charging from the external power supply 10 is also supposed in charging from the motor 30. Namely, when the motor 30 operates as a generator, the ripple current arises in proportion to the output of the motor 30 (torque×rotation speed), and the frequency of this ripple current becomes higher in accordance with the rotation speed of the motor-generator. Therefore, in charging from the motor-generator, there is a possibility that the increase in impedance due to the skin effect amplifies the frequency of the shunt voltage.

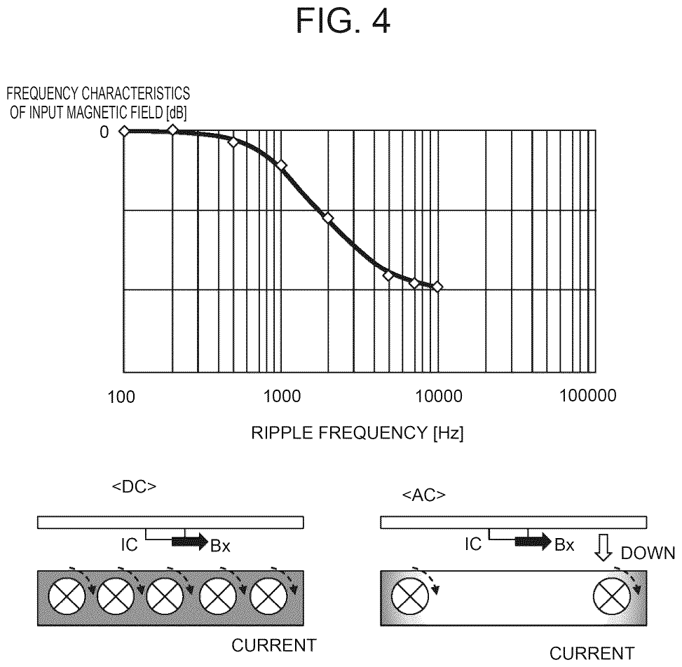

In contrast, the magnetic current sensor has characteristics that the frequency of a magnetic field input to the sensor IC attenuates due to the skin effect. FIG. 4 is a diagram showing an example of frequency characteristics of a magnetic field input to a magnetic current sensor. As understood from FIG. 4, with the magnetic current sensor, the frequency of the magnetic field input to the sensor IC falls in a high frequency band of frequencies of the charging current (ripple current). The reason is because a magnetic field that is near the sensor IC more attenuates as the frequency of the alternating current that comes close to the surface side of the lead (bus bar) due to the skin effect becomes higher.

### 3. Charging Control

As above, in view of accurate detection of the ripple current, it can be said that the magnetic one is superior to the shunt resistor one. Therefore, in an embodiment, a measurement value of the battery current Ib with the magnetic current sensor is used for charging control of the secondary battery 23. In other words, in an embodiment, detection of the ripple current is performed using a magnetism-based measurement value out of measurement values of the battery current Ib with the current sensor 24, not using a shunt resistor-based measurement value out of those, and the chargeable current value Itag[t] is calculated. The shunt resistor-based measurement value is properly used for various kinds of control other than the charging control of the secondary battery 23.

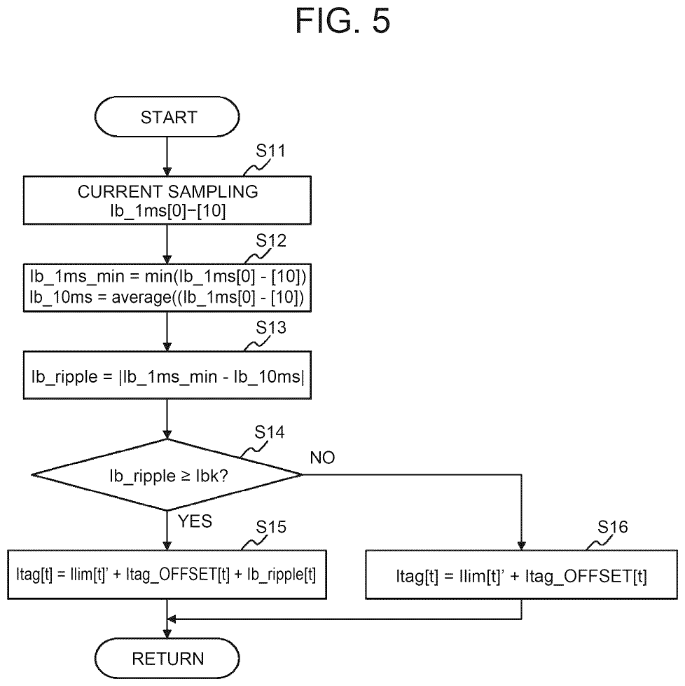

FIG. 5 is a flowchart showing a flow of processing of the charging control of the secondary battery 23 specifically relevant to an embodiment. The routine shown in FIG. 5 is repeatedly performed by the processor of the control apparatus 25, for example, when the processor transmits a charge enabling signal to the external power supply 10 (in other words, when plug-in charging is performed). Otherwise, the routine shown in FIG. 5 is repeatedly performed by the processor of the control apparatus 25 while the motor 30 is operating as the generator.

In the routine shown in FIG. 5, first, sampling of the battery current Ib is performed (step S11). Specifically, as the sampling of the battery current Ib, the currents Ib are detected at intervals of 1 millisecond for 10 milliseconds. The detected battery currents Ib are expressed as Ib_1 ms[0], . . . , Ib_1 ms[10] (Ib_1 ms[0]-[10]).

Subsequently to the processing in step S11, processing in step S12 is performed. In the processing in step S12, there are calculated a minimum value Ib_1 ms_min of the battery currents Ib_1 ms[0], . . . , Ib_1 ms[10] detected in the sampling in step S11, and a 10-millisecond average value Ib_10 ms (average (|Ib_1 ms[0]−[10]|) of these battery currents Ib_1 ms[0], . . . , Ib_1 ms[10].

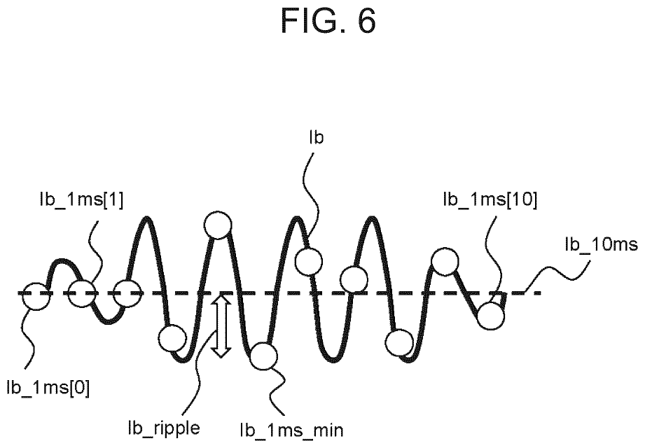

Subsequently to the processing in step S12, processing in step S13 is performed. In the processing in step S13, a ripple current Ib_ripple is calculated. The ripple current Ib_ripple is calculated as the absolute value (|Ib_1 ms_min−Ib_10 ms|) of the difference between the minimum value Ib_1 ms_min and the 10-millisecond average value Ib_10 ms calculated in step S12. Notably, an example of relationship among the battery currents Ib, the minimum value Ib_1 ms_min, and the 10-millisecond average value Ib_10 ms is as shown in FIG. 6.

Subsequently to the processing in step S13, processing in step S14 is performed. In the processing in step S14, it is determined whether or not the ripple current Ib_ripple calculated in the processing in step S13 is not less than a predetermined current value Ibk. For the predetermined current value Ibk, a value preset as a corresponding value to an error of the magnetic current sensor is used.

When the determination result in step S14 is affirmative, it is determined that a ripple is detected, and processing in step S15 is performed. In the processing in step S15, the chargeable current value Itag[t] is set using expression (1) below.

$$Itag [ t ] = {Ilim [ t ]}^{′} + Itag\_OFFSET [ t ] + Ib\_ripple [ t ] \qquad ( 1 )$$

In expression (1), the current value Ilim[t]′ is a value set in accordance with charging performance of the secondary battery 23, and the current value Itag_OFFSET[t] is a value set in accordance with a sensor error and the like. The current value Ib_ripple[t] is the value calculated in the processing in step S13. Notably, the sign of each current value is negative in the case of charging current and positive in the case of discharging current.

When the determination result in step S14 is negative, it is determined that a ripple is not detected, and processing in step S16 is performed. In the processing in step S16, the chargeable current value Itag[t] is set using expression (2) below.

$$Itag [ t ] = {Ilim [ t ]}^{′} + Itag\_OFFSET [ t ] \qquad ( 2 )$$

### 4. Effects

According to the embodiment described above, in the charging control of the secondary battery 23, a ripple is accurately detected using the measurement value of the battery current Ib with the magnetic current sensor. Further, when the detected ripple current Ib_ripple is not less than the predetermined current value Ibk, the chargeable current value Itag is set using the detected ripple current Ib_ripple. Accordingly, a defect in the case of performing charging control of the secondary battery 23 using the measurement value of the battery current Ib with the shunt resistor current sensor can be restrained from occurring.

What is claimed is:

1. A charging system for a secondary battery, the charging system comprising:
a current sensor that measures a current flowing in the secondary battery; and
a control apparatus that, during charging of the secondary battery, refers to a measurement value of the current sensor and performs charging control of the secondary battery, wherein:
the current sensor includes a magnetic current sensor;
the charging control includes setting of a chargeable current value that is allowed during the charging of the secondary battery; and
when a ripple is detected from the measurement value of the magnetic current sensor and a current value of the detected ripple is not less than a predetermined current value, the chargeable current value is set using the current value of the detected ripple.

2. The charging system for a secondary battery according to claim 1, wherein when a ripple is detected from the measurement value of the magnetic current sensor and a current value of the detected ripple is less than the predetermined current value, the chargeable current value is set not using the current value of the detected ripple.

3. The charging system for a secondary battery according to claim 1, wherein:
the current sensor further includes a shunt resistor current sensor; and
a measurement value of the shunt resistor current sensor is not used for the detection of the ripple.

4. The charging system for a secondary battery according to claim 1, wherein the magnetic current sensor is a core-including current sensor having a magnetic core or a coreless current sensor not having a magnetic core.

5. A charging method for a secondary battery, the charging method comprising:
measuring a current flowing in the secondary battery with a current sensor; and
during charging of the secondary battery, a control apparatus referring to a measurement value of the current sensor and performing charging control of the secondary battery, wherein:
the current sensor includes a magnetic current sensor;
the charging control includes setting of a chargeable current value that is allowed during the charging of the secondary battery; and
when a ripple is detected from the measurement value of the magnetic current sensor and a current value of the detected ripple is not less than a predetermined current value, the chargeable current value is set using the current value of the detected ripple.
